(19) United States
(12) Patent Application Publication
(10) Pub. No.: US 2008/0019084 A1
(43) Pub. Date: Jan. 24, 2008

(54) Display device

(75) Inventors: Gyu Min Lee, Yongin-si (KR); Myeong Gil Kim, Suwon-si (KR)

Correspondence Address: ROYLANCE, ABRAMS, BERDO & GOODMAN, L.L.P., 1300 19TH STREET, N.W., SUITE 600, WASHINGTON,, DC, 20036, US

(73) Assignee: Samsung Electronics Co., Ltd.

(21) Appl. No.: 11/822,344

(22) Filed: Jul. 5, 2007

(30) Foreign Application Priority Data
Jul. 21, 2006 (JP) 2006-68614
Jul. 21, 2006 (JP) 2006-68615

(51) Int. Cl. H05K 5/03; F16B 37/04

(52) U.S. Cl. 361/679; 411/172; 411/177

(57) ABSTRACT

A display device includes a front case and a rear case that accommodate internal components, a fixing screw for coupling the front case and the rear case or coupling the internal components, and a nut into which the fixing screw is coupled. The nut has a shock-absorbing part at an outer portion thereof. A nut supporting part is disposed at the front case and/or the rear case to support the nut. Accordingly, deformation of the case caused by tightening the fixing screw is substantially prevented.

### CROSS-REFERENCE TO RELATED APPLICATION

This application claims the benefit under 35 U.S.C. §119(a) of Korean Patent Application Nos. 2006-0068614 and 2006-0068615, filed on Jul. 21, 2006 in the Korean Intellectual Property Office, the entire disclosures of both of which are hereby incorporated by reference.

### BACKGROUND OF THE INVENTION

1. Field of the Invention

The present invention relates to a display device. More particularly, the present invention relates to a display device in which deformation of a case caused by tightening of fixing screws is substantially prevented.

2. Description of the Related Art

Generally, a display device, such as a monitor, a TV or the like, includes a display module for displaying an image, and a case for protecting the display module. Typically, the display module is fixed to an inner surface of the case by tightening fixing screws, and elements of the case are coupled to each other by tightening the fixing screws.

Korean Patent Laid-open Publication No. 2004-63651 discloses a conventional display device that is provided with screw-coupling parts for coupling a rear case and a Plasma Display Panel (PDP) module to a front case by tightening fixing screws. The screw-coupling part is formed integrally with the front case, and protrudes from an inner surface of the front case toward the PDP module. The screw-coupling part is formed with a screw hole at its central portion through which the fixing screw is tightened, and has reinforcing ribs at its periphery.

However, because the screw-coupling part is formed integrally with the front case, deformation of the screw-coupling part generated when the fixing screw is tightened may cause deformation of a front surface of the front case, thereby deteriorating the quality of an external appearance. Particularly, as the fixing screw advances into the screw hole of the screw-coupling part, the screw-coupling part is expandedly deformed, and the front surface of the front case is pulled rearwardly in reaction thereto. Additionally, because a torque generated when tightening the fixing screw is transferred to the front surface of the front case through the screw-coupling part, the front surface of the front case is distorted.

Accordingly, a need exists for a display device in which a case is substantially prevented from being deformed when tightening a fixing screw.

### SUMMARY OF THE INVENTION

An aspect of exemplary embodiments of the present invention is to provide a display device in which deformation of a case caused by tightening fixing screws is substantially prevented.

An exemplary embodiment of the present invention provides a display device comprising a front case and a rear case that accommodate internal components, a fixing screw for coupling the front case and the rear case or coupling the internal components, and a nut into which the fixing screw is coupled. The nut has a shock-absorbing part at an outer portion thereof. A nut supporting part is disposed at the front case and/or the rear case to support the nut.

Preferably, the front case is formed with an opening, and the internal components include a display module for displaying an image.

Preferably, the display module is a plasma display panel (PDP) module.

Preferably, the nut supporting part includes a holding space for holding the nut while substantially preventing rotation of the nut.

Preferably, the nut supporting part further includes first and second supporting members that are spaced apart from each other and extend from an inner surface of either the front case or the rear case, a third supporting member having both ends connected to the first and second supporting members to support a first surface of the nut, and a fourth supporting member having both ends connected to the first and second supporting members to support a second surface of the nut opposite to the first surface.

Preferably, the third supporting member is formed with a through-hole through which the fixing screw passes.

Preferably, the fourth supporting member is spaced apart from the inner surface of either the front case or the rear case.

Preferably, the shock-absorbing part of the nut has a hexahedron shape.

Another exemplary embodiment of the present invention provides a display device comprising a front case and a rear case that accommodate internal components, a fixing screw for coupling the front case and the rear case or coupling the internal components, a nut into which the fixing screw is coupled, and a nut supporting part disposed at the front case and/or the rear case to support the nut.

Another exemplary embodiment of the present invention provides a display device comprising a front case and a rear case that accommodate internal components, a fixing screw for coupling the front case and the rear case or coupling the internal components, an elastic shock-absorbing nut into which the fixing screw is coupled, and a nut supporting part disposed at the front case and/or the rear case to supportingly accommodate the shock-absorbing nut.

Preferably, the shock-absorbing nut has a substantially cylindrical shape, and the nut supporting part includes a cylindrical nut accommodating member for accommodating the shock-absorbing nut.

Preferably, the nut supporting part further includes first and second supporting members extending from an inner surface of the front case or the rear case and are disposed apart from the nut accommodating member oppositely to each other, and third and fourth supporting members connecting an outer surface of the nut accommodating member and the first and second supporting members, respectively.

Preferably, the nut supporting part further includes a fifth supporting member having both ends connected to the first and second supporting members to support lower ends of the third and fourth supporting members and the nut accommodating member.

Preferably, a lower portion of the fifth supporting member is spaced apart from the inner surface of the front case or the rear case.

Additional aspects and/or advantages of the invention are set forth in part in the following description and, in part, will be obvious from the description, or may be learned by practice of the invention.

### BRIEF DESCRIPTION OF THE DRAWINGS

These and/or other aspects and advantages of the exemplary embodiments of the invention will become apparent and more readily appreciated from the following description of the exemplary embodiments, taken in conjunction with the accompanying drawings, of which:

FIG. 1 is an exploded perspective view of a display device in accordance with an exemplary embodiment of the present invention;

FIG. 2 is an exploded perspective view of a screw-coupling part in accordance with a first exemplary embodiment of the present invention;

FIG. 3 is a sectional view of a screw-coupling part in accordance with a first exemplary embodiment of the present invention;

FIG. 4 is an exploded perspective view of a screw-coupling part in accordance with a second exemplary embodiment of the present invention; and

FIG. 5 is a sectional view of a screw-coupling part in accordance with a second exemplary embodiment of the present invention.

Throughout the drawings, the same drawing reference numerals will be understood to refer to the same elements, features, and structures.

### DETAILED DESCRIPTION OF EXEMPLARY EMBODIMENTS

Reference will now be made in detail to exemplary embodiments of the present invention, examples of which are illustrated in the accompanying drawings. Exemplary embodiments are described below to explain the present invention by referring to the figures.

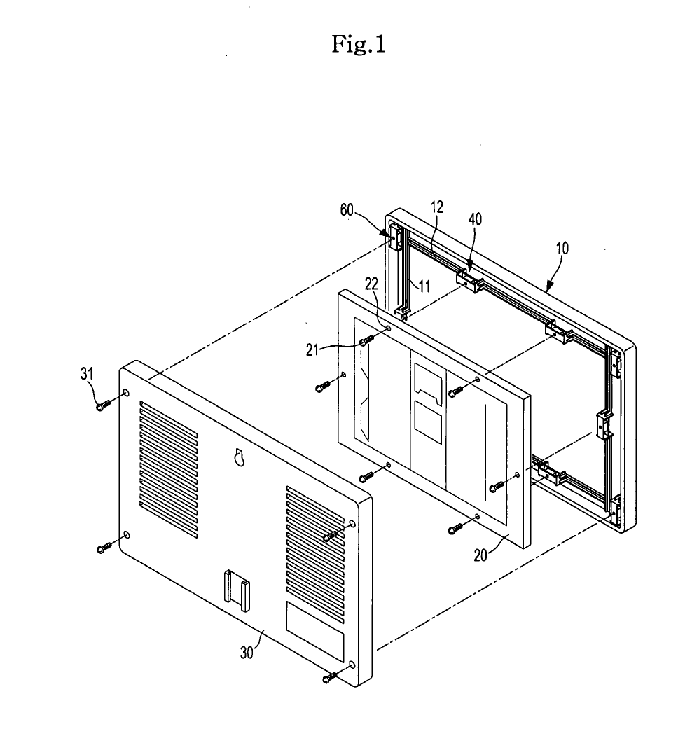

FIG. 1 shows a plasma display panel (PDP) television (TV) as an example of a display device according to an exemplary embodiment of the present invention. As shown in FIG. 1, a TV comprises a front case 10 having an opening 11, a PDP module 20 fixed to an inner surface of the front case 10 and displaying an image, and a rear case 30 coupled to a rear surface of the front case 10 for covering the PDP module 20.

Although not illustrated in detail in the drawing, the PDP module 20 includes a PDP panel, a driving part for driving the PDP panel, a signal processing part for processing an image signal, and a power supply part for supplying power to the respective components.

The PDP module 20 is coupled to the inner surface of the front case 10 by tightening a plurality of fixing screws 21 into the inner surface of the front case 10 through through-holes 22 formed along a border of the PDP module 20. A plurality of first screw-coupling parts 40 are disposed at the inner surface of the front case 10 and into which the fixing screws 21 are tightened. Reinforcing ribs 12 are formed at the inner surface of the front case 10 to reinforce a periphery of the opening 11. The first screw-coupling parts 40 are disposed on the reinforcing ribs 12 for supporting the first screw-coupling parts 40 by the reinforcing ribs 12.

The rear case 30 is coupled to the front case 10 by tightening fixing screws 31 through four corners of the rear case 30, as shown in FIG. 1. The front case 10 is formed with second screw-coupling parts 60 at its four corners into which the fixing screws 31 are tightened. The second screw-coupling parts 60 are preferably formed at the corners of the front case 10, however, the second screw-coupling parts 60 may be additionally provided at other positions.

The first screw-coupling part 40 for coupling the PDP module 20 has substantially the same shape as the second screw-coupling part 60 for coupling the rear case 30. Accordingly, to provide a clear and concise explanation, only the first screw-coupling part 40 is described hereinafter. For the convenience of description, the first screw-coupling part 40 will be hereinafter called a “screw-coupling part”.

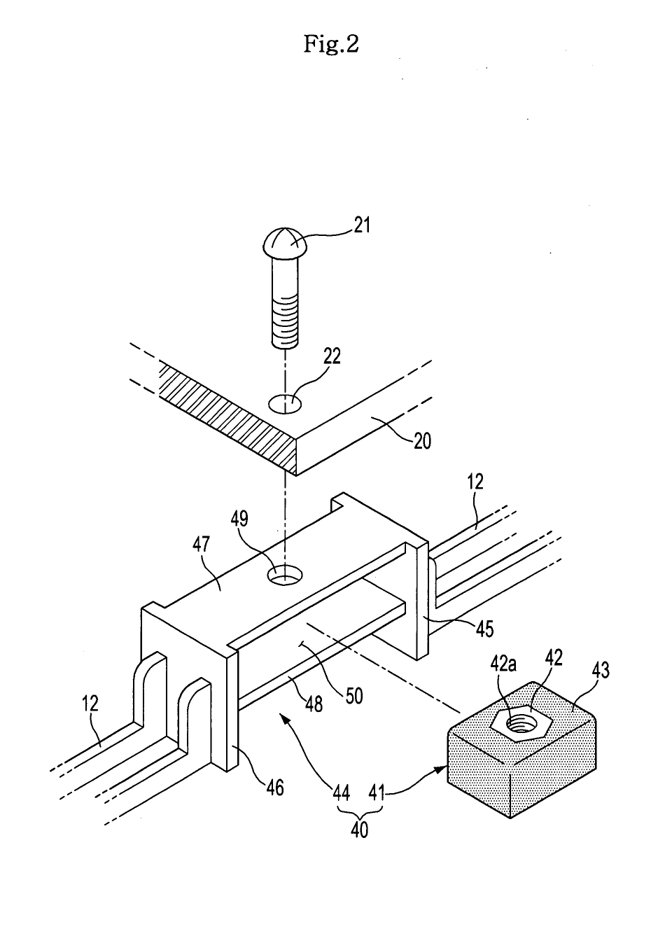

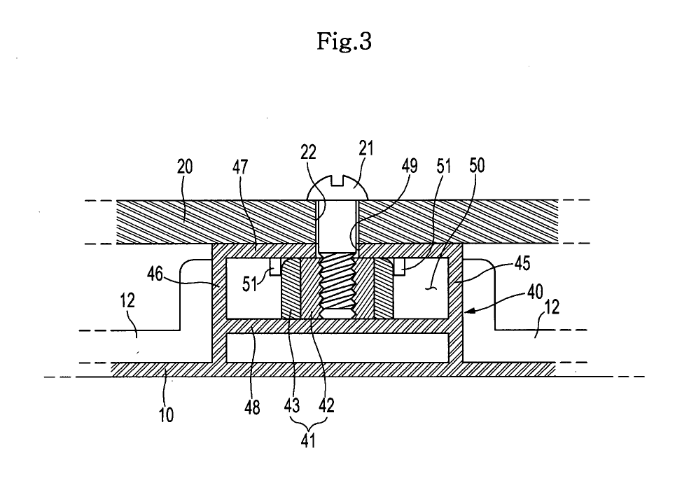

FIGS. 2 and 3 show the screw-coupling part in accordance with a first exemplary embodiment of the present invention. The screw-coupling part 40 includes a nut 41 to which the fixing screw 21 is coupled and a nut supporting part 44 disposed at the inner surface of the front case 10 to supportingly hold the nut 41.

The nut 41 has a metallic coupling part 42 in which a screw hole 42a is formed and a shock-absorbing part 43 coupled to an outer surface of the coupling part 42 surrounding the same. The shock-absorbing part 43 is made from elastic material, such as rubber, silicone, soft resin or the like that has a feature of absorbing shocks. When tightening the fixing screw 21, the shock-absorbing part 43 decreases a torque that is transferred to the nut supporting part 44 from the fixing screw 21, thereby minimizing deformation of the nut supporting part 44. Additionally, the shock-absorbing part 43 also has a function of preventing the nut 41 from being loosened by friction.

Although the nut 41 is illustrated as having a hexahedron shape (that is, the external appearance of the shock-absorbing part 43) in FIG. 2, the shape of the nut 41 may be widely varied to the extent that the nut 41 is able to receive the fixing screw 21. From a point of view of facilitation of mounting the nut 41 to the nut supporting part 44 and restriction of the rotation of the nut 41 after being mounted, it is most preferable to use the hexahedron-shaped nut 41.

The nut supporting part 44 includes first and second supporting members 45 and 46 that are spaced apart from each other and extend toward the PDP module 20 from the inner surface of the front case 10. A third supporting member 47 has both ends connected to upper ends of the first and second supporting parts 45 and 46 to support an upper surface (in an upper direction in FIG. 3) of the nut 41. A fourth supporting member 48 has both ends connected to side surfaces of the first and second supporting members 45 and 46 to support a lower surface (in a lower direction in FIG. 3) of the nut 41.

The first to fourth supporting members 45, 46, 47 and 48 are substantially plate shapes and have widths corresponding to a width of the nut 41. The third supporting member 47 is formed with a through-hole 49 through which the fixing screw 21 passes to be tightened into the nut 41. The side surfaces of the first and second supporting members 45 and 46 are supported by the reinforcing ribs 12. The fourth supporting member 48 is spaced from the inner surface of the front case 10 to substantially prevent torque from being transferred to the front case 10 when tightening the fixing screw 21.

Guide protrusions 51 are formed at a lower surface of the third supporting member 47. The guide protrusions 51 guide the insertion of the nut 41 in a nut holding space 50 between the third supporting member 47 and the fourth supporting member 48 so that the screw hole 42a of the nut 41 is aligned with the through-hole 49 of the third supporting member 47. Additionally, the guide protrusions 51 substantially prevent the rotation of the nut 41 after being inserted in the nut holding space 50. The nut supporting part 44 may be formed integrally with the front case 10, or may be separately manufactured and then coupled to the front case 10.

When coupling the PDP module 20 by using the screw-coupling part 40, the nut 41 is first inserted into the nut holding space 50 of the nut supporting part 44, and the through-hole 22 of the PDP module 20 is aligned with the through-hole 49 of the nut supporting part 44. Then, the fixing screw 21 is tightened into the nut 41 through the through-holes 22 and 49.

In such a coupling process, when the nut 41 is inserted into the nut holding space 50, because the nut 41 is guided by the guide protrusions 51, the screw hole 42a of the nut 41 may be easily aligned with the through-hole 49 of the nut supporting part 44. Additionally, because the nut 41 held by the nut supporting part 44 is substantially prevented from being rotated by the guide protrusions 51, the fixing screw 21 may be easily coupled to the nut 41, such that it is unnecessary to grasp the nut 41 when tightening the fixing screw 21.

Because the nut 41 is a separate component from the nut supporting part 44 and has the shock-absorbing part 43, the torque transferred to the nut 41 when tightening the fixing screw 21 is minimally transferred to the nut supporting part 44. Thus, the nut supporting part 44 is substantially prevented from being deformed. Because the nut 41 is provided separately from the nut supporting part 44, the direct transfer of the torque may be avoided. Further, the shock-absorbing part 43 of the nut 41 minimizes the torque transferred to the nut supporting part 44. Even if the torque is transferred to the nut supporting part 44, because the fourth supporting member 48 of the nut supporting part 44 is spaced from the inner surface of the front case 10, the front case 10 is substantially prevented from being deformed. Conclusively, the above-described screw coupling structure substantially prevents the deterioration of the quality of the external appearance of the front case 10.

The first and second screw-coupling parts 40 and 60 of exemplary embodiments of the present invention are not limited to the PDP TV but may also be applied to all kinds of electronic devices in which fixing screws are used for coupling internal components to a case.

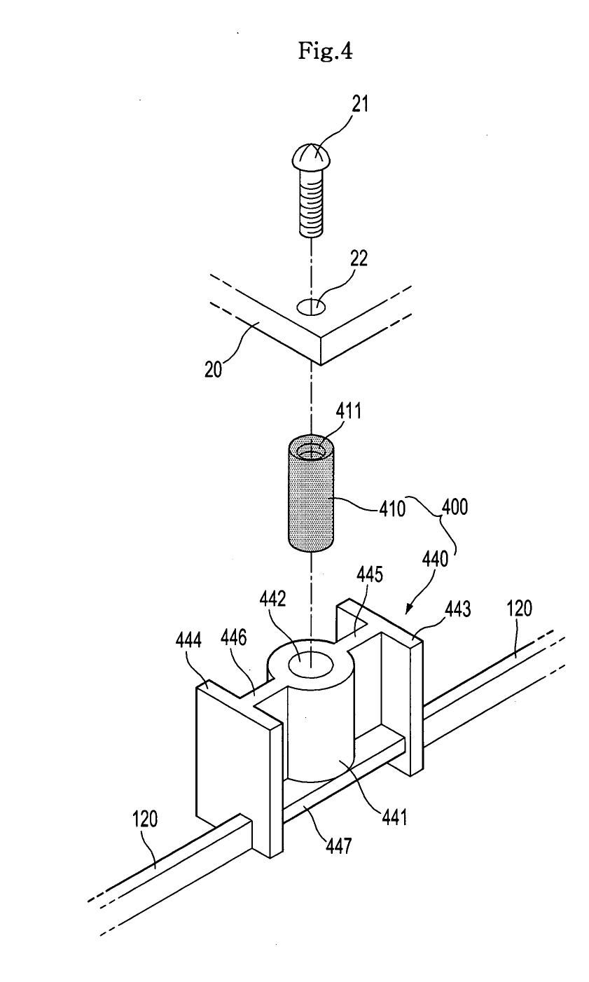

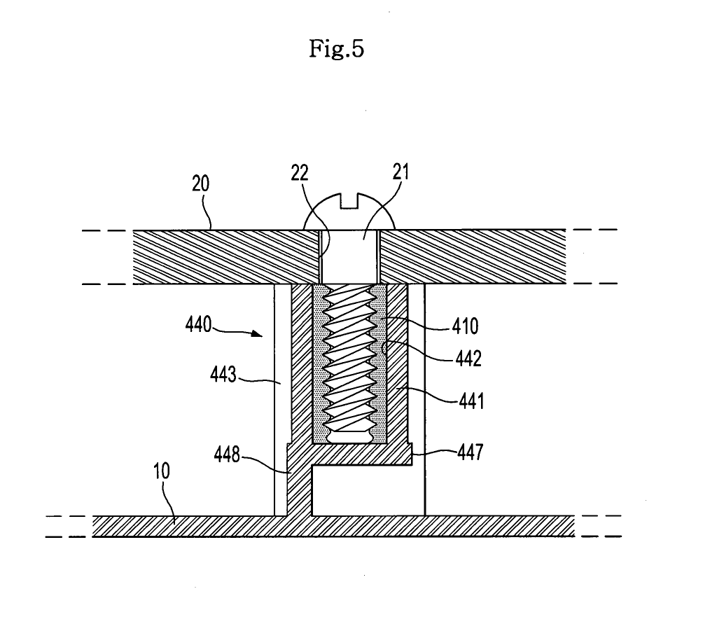

FIGS. 4 and 5 show a screw-coupling part in accordance with a second exemplary embodiment of the present invention. A screw-coupling part 400 includes a shock-absorbing nut 410 to which the fixing screw 21 is coupled and a nut supporting part 440 disposed at the inner surface of the front case 10 to supportingly hold the shock-absorbing nut 410.

The shock-absorbing nut 410 is formed in a substantially cylindrical shape and has a screw hole 411 into which the fixing screw 21 is tightened. The shock-absorbing nut 410 is made from elastic material, such as rubber, silicone, soft resin or the like that has a feature of absorbing shocks. When tightening the fixing screw 21, the shock-absorbing nut 410 decreases the torque transferred to the nut supporting part 440 from the fixing screw 21, and minimizes the deformation of the nut supporting part 440.

The nut supporting part 440 includes a cylindrical nut accommodating member 441 having an accommodating space 442 for accommodating the shock-absorbing nut 410, first and second supporting members 443 and 444 that support the nut accommodating member 441, third and fourth supporting members 445 and 446, and a fifth supporting member 447. The first and second supporting members 443 and 444 extend from the inner surface of the front case 10, and are spaced apart from the nut accommodating member 441 oppositely to each other. The third and fourth supporting members 445 and 446 connect an outer surface of the nut accommodating member 441 and the first and second supporting members 443 and 444, respectively. The fifth supporting member 447 is connected to side surfaces of the first and second supporting members 443 and 444 at both ends to support lower ends of the third and fourth supporting members 445 and 446 and the nut accommodating member 441.

As shown in FIG. 5, a lower portion of the nut accommodating member 441, more particularly, the fifth supporting member 447, is connected to the front case 10 by a one-sided connecting member 448, and most other portions of the fifth supporting member 447 are spaced from the inner surface of the front case 10. Accordingly, the torque transferred to the nut supporting part 440 when tightening the fixing screw 21 is minimally transferred to the front case 10, and the front case 10 is substantially prevented from being deformed. The nut supporting part 440 may be formed integrally with the front case 10, or may be separately manufactured and then coupled to the front case 10.

When coupling the PDP module 20 by using the screw-coupling part 400 according to a second exemplary embodiment of the present invention, the shock-absorbing nut 410 is first inserted in the nut accommodating member 441 of the nut supporting part 440, and the through-hole 22 of the PDP module 20 is aligned with the screw hole 411 of the shock-absorbing nut 410. Then, the fixing screw 21 is tightened into the shock-absorbing nut 410. At this time, the screw hole 411 of the shock-absorbing nut 410 is expandedly deformed, and an outer surface of the shock-absorbing nut 410 is pressed to closely contact an inner surface of the accommodating space 442 of the nut accommodating member 441. Accordingly, because the shock-absorbing nut 410, into which the fixing screw 21 is tightened, is not separated from the nut accommodating member 441, the PDP module 20 may be kept in a securely coupled state.

In such a coupling process, the shock-absorbing nut 410 performs a shock-absorbing effect by its own elastic deformation. Accordingly, torque generated when tightening the fixing screw 21 is minimally transferred to the nut supporting part 440, thereby substantially preventing the deformation of the nut supporting part 440. Furthermore, because the shock-absorbing nut 410 is provided separately from the nut supporting part 440, the direct transfer of torque may be avoided, and the torque transferred to the nut supporting part 440 is minimized by the shock-absorbing effect of the shock-absorbing nut 410. Even if torque is transferred to the nut supporting part 440, because the majority of the fifth supporting member 447 is spaced apart from the inner surface of the front case 10, the front case 10 is substantially prevented from being deformed. Conclusively, the above-described screw coupling structure substantially prevents the deterioration of the quality of the external appearance of the front case 10.

As apparent from the above description, according to the display device of exemplary embodiments of the present invention, because the nut and the nut supporting part of the screw-coupling part are separate components, the direct transfer of torque to the case when tightening the fixing screw may be avoided, and the deformation of the case is substantially prevented. Accordingly, the deterioration of the quality of the external appearance of the front case may be prevented.

Additionally, because the nut is provided with the shock-absorbing part, the torque transferred to the case when tightening the fixing screw may be minimized by the shock-absorbing effect of the shock-absorbing part, whereby the deformation of the case is substantially prevented.

Additionally, because the shock-absorbing nut and the nut supporting part of the screw-coupling part are separate components and the shock-absorbing nut has a shock-absorbing function, the direct transfer of torque to the case when tightening the fixing screw may be avoided, and the deformation of the case is substantially prevented.

Although exemplary embodiments of the present invention have been shown and described, it would be appreciated by those skilled in the art that changes may be made in these exemplary embodiments without departing from the principles and spirit of the invention, the scope of which is defined in the claims and their equivalents.

What is claimed is:

1. A display device, comprising:
a front case;
a rear case;
components accommodated between the front and rear cases;
a fixing screw for coupling the front case and the rear case or for coupling the components to the front and/or rear case;
a nut for receiving the fixing screw, the nut having a shock-absorbing portion; and
a nut supporting part disposed at the front case and/or the rear case for supporting the nut.

2. The display device according to claim 1, wherein
the front case is formed with an opening; and
the components include a display module for displaying an image.

3. The display device according to claim 2, wherein the display module is a plasma display panel (PDP) module.

4. The display device according to claim 1, wherein the nut supporting part includes a holding space for holding the nut and substantially preventing rotation of the nut when receiving the fixing screw.

5. The display device according to claim 4, wherein the nut supporting part further includes
first and second supporting members spaced from each other and extending from an inner surface of either the front case or the rear case;
a third supporting member, both ends of which are connected to the first and second supporting members for supporting a first surface of the nut; and
a fourth supporting member, both ends of which are connected to the first and second supporting members for supporting a second surface of the nut opposite to the first surface.

6. The display device according to claim 5, wherein the third supporting member has a through-hole through which the fixing screw passes.

7. The display device according to claim 5, wherein the fourth supporting member is spaced from the inner surface of either the front case or the rear case.

8. The display device according to claim 5, wherein the shock-absorbing part of the nut has a substantially hexahedron shape.

9. The display device according to claim 1, wherein the shock-absorbing portion of the nut surrounds a fixing screw receiving portion.

10. The display device according to claim 5, wherein at least two guide protrusions extend from the third supporting member and are spaced to receive the nut therebetween.

11. A display device, comprising:
a front case;
a rear case;
components accommodated between the front and rear cases;
a fixing screw for coupling the front case and the rear case or for coupling the components to the front and/or rear case;
a nut into which the fixing screw is coupled; and
a nut supporting part disposed at the front case and/or the rear case to support the nut.

12. The display device according to claim 11, wherein the nut supporting part includes
first and second supporting members spaced from each other and extending from an inner surface of either the front case or the rear case;
a third supporting member, both ends of which are connected to the first and second supporting members for supporting a first surface of the nut; and
a fourth supporting member, both ends of which are connected to the first and second supporting members for supporting a second surface of the nut opposite to the first surface.

13. A display device, comprising:
a front case;
a rear case;
components accommodated between the first and second cases;
a fixing screw for coupling the front case and the rear case or for coupling the components to the front and/or rear case;
an elastic shock-absorbing nut for receiving the fixing screw; and
a nut supporting part disposed at the front case and/or the rear case for supportingly accommodating the shock-absorbing nut.

14. The display device according to claim 13, wherein
the front case has an opening, and
the components include a display module for displaying an image.

15. The display device according to claim 14, wherein the display module is a plasma display panel (PDP) module.

16. The display device according to claim 13, wherein
the shock-absorbing nut has a substantially cylindrical shape, and
the nut supporting part includes a substantially cylindrical nut accommodating member for accommodating the shock-absorbing nut.

17. The display device according to claim 16, wherein the nut supporting part further includes
first and second supporting members extending from an inner surface of the front case or the rear case and on opposite sides of the nut accommodating member from each other;and
third and fourth supporting members connecting an outer surface of the nut accommodating member and the first and second supporting members, respectively.

18. The display device according to claim 17, wherein a lower portion of the nut accommodating member is spaced from the inner surface of the front case or the rear case.

19. The display device according to claim 17, wherein the nut supporting part further includes a fifth supporting member, both ends of which are connected to the first and second supporting members for supporting lower ends of the third and fourth supporting members and the nut accommodating member.

20. The display device according to claim 19, wherein a lower portion of the fifth supporting member is spaced apart from the inner surface of the front case or the rear case.

21. A display device, comprising:
a fixing screw for coupling a first member and a second member;
a nut for receiving the fixing screw; and
a nut supporting part disposed at the first member for supporting the nut and having an opening for receiving the fixing screw.

22. The display device according to claim 21, wherein the first member is a front case and the second member is a rear case.

23. The display device according to claim 22, wherein the first member is a front case and the second member is an internal component disposed between the front case and a rear case.

24. The display device according to claim 21, wherein the nut supporting part further includes
first and second supporting members spaced from each other and extending from an inner surface of the first member;
a third supporting member, both ends of which are connected to the first and second supporting members for supporting a first surface of the nut; and
a fourth supporting member, both ends of which are connected to the first and second supporting members for supporting a second surface of the nut opposite to the first surface.

25. The display device according to claim 24, wherein the opening in the nut supporting part for receiving the fixing screw is in the third supporting member.

26. The display device according to claim 21, wherein
the shock-absorbing nut has a substantially cylindrical shape, and
the nut supporting part includes a substantially cylindrical nut accommodating member for accommodating the shock-absorbing nut.

27. The display device according to claim 26, wherein the nut supporting part further includes
first and second supporting members extending from an inner surface of the first member and on opposite sides of the nut accommodating member from each other; and
third and fourth supporting members connecting an outer surface of the nut accommodating member and the first and second supporting members, respectively.

28. The display device according to claim 27, wherein a lower portion of the nut accommodating member is spaced from the inner surface of the first member.

29. The display device according to claim 27, wherein the nut supporting part further includes a fifth supporting member, both ends of which are connected to the first and second supporting members for supporting lower ends of the third and fourth supporting members and the nut accommodating member.

30. The display device according to claim 29, wherein a lower portion of the fifth supporting member is spaced apart from the inner surface of the first member.
